(19) United States
(12) Patent Application Publication
(10) Pub. No.: US 2006/0278866 A1
(43) Pub. Date: Dec. 14, 2006

(54) Nanotube optoelectronic memory devices

(76) Inventor: Alexander Star, Albany, CA (US)

Correspondence Address: Alexander Star, 5465 Pocusset Street, Pittsburgh, PA, 15217, US

(21) Appl. No.: 11/147,535

(22) Filed: Jun. 8, 2005

(51) Int. Cl. H01L 29/06

(52) U.S. Cl. 257/17

(57) ABSTRACT

Nanotube transistors are coated with optically responsive agents to form optoelectronic detectors. In response to illumination, an electronic property of the inventive detector changes from one value to another. It retains the new value when the illumination is removed, so that the detector remembers having been illuminated. The detector can be reset by changing a gate voltage. Spectral response of the detectors can be changed by using different agents as coating. Multiple detectors with different agents can be combined on one substrate to form a combined detector that discriminates between radiation of different wavelengths.

### FIELD OF INVENTION

The present invention relates to electrical detection of optical signals using nanotube transistors modified to detect specific bandwidths of optical radiation. The invention provides a device for measuring signals and method for its operation.

### BACKGROUND OF THE INVENTION

Electrical detection of optical signals is important for many devices, ranging from optoelectronic couplers to video cameras. To meet this need, a variety of optically responsive semiconductor devices are known in the art. The simplest, photodiodes, are active devices containing semiconductor junctions. When a photodiode is exposed to light within the absorption band of the semiconductor, it absorbs photons which excite charge carriers. If the semiconductor junction is biased forward by two electrodes, the excited charge carriers cause an increased current between the two electrodes. Photodiodes are disadvantageous because they require high levels of power to operate. They are therefore inappropriate for systems like cameras, which run on batteries.

In most cameras, a more complicated device called a charge-coupled device array is used. One pixel of such an array contains semiconductor material. Light within the absorption band of the semiconductor excites charge carriers. Unlike in photodiodes, the carriers are not detected immediately, but are allowed to accumulate over a fixed amount of time. After they have accumulated in each pixel, the charges in the various pixels within a row are shifted down the row and measured sequentially. Very little current or power is used during the measurement. However, charge-coupled devices are relatively slow, because of the sequential readout

Conventional electronic detection techniques suffer a further drawback in that they respond to optical signal within the bandwidth of the semiconductor material. To make a color camera, it is necessary to narrow the response of the detection system. A colored filter placed above the semiconductor restricts the wavelength of the radiation which reaches it.

### DESCRIPTION OF THE INVENTION

Embodiments of the invention provide a detection device that operates at low power and high speed, and for which the response bandwidth can be tuned directly without filters. The device comprises nanotubes, configured into transistors, and optically responsive agents coating the nanotubes.

First, nanotube transistors are known in the art. As used here, ‘nanotube’ means a structure having a width less than 100 nm and a length greater than 100 nm, where the length is at least 100 times greater than the width. Many examples of nanotubes are known in the art, including, but not limited to, multi-walled carbon nanotubes, single-walled carbon nanotubes, double-walled carbon nanotubes, single-walled carbon nanotube ropes, boron nitride nanotubes, tungsten disulfide nanotubes, semiconductor nanowires, semiconductor nanorods, and silicon nanowires. ‘Transistor’ means an active electronic device comprising a semiconducting channel, at least two electrodes which can pass current through the semiconducting channel, and a gate terminal which can apply an electric field to the semiconducting channel.

A nanotube transistor includes at least one nanotube disposed on a substrate, the at least one nanotube serving as the semiconducting channel. The transistor may include only one nanotube which spans the distance from one electrode to another. Alternatively, it may include several such nanotubes. Further, it may include many nanotubes arranged as a network, where no individual nanotube spans the complete distance between the electrodes. Each nanotube contacts several other nanotubes. Because there are many nanotubes on the substrate, there are many conducting paths between the two electrodes. The at least one nanotube may be disposed on the substrate by means of chemical vapor deposition, by random deposition from solution, by AFM manipulation, or by other methods known in the art. A nanotube network prepared by chemical vapor deposition is disclosed in Application PCT/US2003/019808, by Jean-Christophe Gabriel et al., “Dispersed growth of nanotubes on a substrate,” which is incorporated herein in its entirety by reference. The invention also contemplates other methods, known in the art, for preparing at least one nanotube disposed on a substrate.

An ‘electrode’ means an element made from a conductive material which is disposed on the substrate and configured to make electrical contact with the at least one nanotube. Preferably, an electrode is formed in a pattern such as a line. The conductive material may be a metal, including, but not limited to, gold, titanium, chromium, iron, palladium, and an alloy of palladium. Alternatively, the conductive material may be a conducting nanotube.

A ‘gate terminal’ means a conductive material which is separated from the at least one nanotube by a dielectric material. The conductive material may be a metal, including, but not limited to, gold, titanium, chromium, iron, palladium, and an alloy of palladium. Alternatively, the conductive material may be a conducting nanotube. The dielectric material is any material which is substantially incapable of conducting electrical current. Many examples are known in the art, including, but not limited to, silicon oxide, silicon nitride, aluminum oxide, strontium titanium oxide, hafnium oxide, metal oxides, insulating polymers, and insulating liquids.

The electrodes may be used to measure an electrical property of the at least one nanotube, including but not limited to electrical resistance, conductance, or current. A gate voltage is applied between the gate terminat and the electrodes. The electrical property has a different value for different values of the gate voltage.

The nanotube transistor is modified by coating the at least one nanotube with an optically responsive agent. An optically responsive agent is a chemical which absorbs optical radiation within a band of wavelengths and absorbs radiation only weakly at higher and lower wavelengths. Optical radiation includes electromagnetic radiation with wavelengths less than 2 micrometers and greater than 100 nanometers, such as infrared radiation, visible light, and ultraviolet light. Many examples of optically responsive agents are known in the art, including, but not limited to, poly {(m-phenylenevinylene)-co-[(2,5-dioctyloxy-p-phenylene)vinylene]} (PmPV), regioregular poly(3-octylthiophene-2,5-diyl) (P3OT), and other photoactive polymers. Optically responsive agents include synthetic polymers, such as poly(phenylene vinylene) (PPV) and related polymers (MEH-PPV, PmPV, PpyPV, etc.), poly(phenylene ethylene), poly(para-phenylene) (PPP), poly(thiophene)s, and polyaniline (PANi); dendrimers based on transition-metal complexes; and synthetic porphyrins and phthalocyanines as well as their metal complexes.

As used here, ‘coating’ means that at least a portion of the at least one nanotube is in intimate physical contact with the agent. An agent coating a nanotube is physically adsorbed to a portion of the nanotube surface. In some embodiments, the agent is also adsorbed to the substrate of the transistor. Many methods of coating nanotubes are known in the literature, including, but not limited to, polymer-wrapped nanotubes, as in Star et al., Angew. Chem. Int. Ed. 40: 1721-1725 (2001); PmPV-coated nanotubes, as in Curran et al., Adv. Mater. 10: 1091-1093 (1998); and polyacrylonitride-coated nanotubes, which are all included by reference herein However, the invention provides that at least a portion of the at least one nanotube is in intimate physical contact with the substrate.

The optically responsive agent may be deposited on a device using various methods, depending on the material to be deposited. For example, the agent may be deposited by drop casting, in which a droplet of solution containing the agent is placed on a device. Also, the agent may be deposited by dip coating. In this method, a device is soaked in a solution containing the agent. Further, the agent may be spin-coated onto a device; in this method, the device is spinning at a high speed when a droplet of solution is placed on it. Other coating methods are also known in the art. The details of a coating method depend on the identity of the optically responsive agent and the design of the device and its substrate.

When the nanotube transistor and the optically responsive agent are so arranged, the device operates as an optical sensor with advantageous properties. It responds to light only within the absorption band of the optically responsive agent. Thus, to make a sensor for a different color, one need only use a different agent. When the sensor is exposed to light, it responds rapidly by means of a change in the transistor's electrical resistance. The change in resistance is independent of the amount of current used to measure the resistance. Unlike a photodiode, the device can be measured with very small amounts of power. And unlike a charge-coupled device, the device can be measured on its own, without transferring the electrical properties to a neighboring device. Finally, the change in resistance remains even after the light is removed. This feature enables the construction of cameras in which multiple sensors can first be exposed for a fixed duration of time and next be measured. After the sensors are measured, they can be reset by changing the gate voltage.

### EXAMPLE 1

Single-walled carbon nanotubes were deposited on a silicon oxide layer on a conducting silicon substrate, the conducting substrate serving as the gate terminal. The nanotubes were arranged as a network of mostly semiconducting and a few metallic nanotubes. The density of nanotubes was such that the network functioned as a semiconductor. This arrangement was achieved by growing the nanotubes in place using chemical vapor deposition, using the methods and conditions described in application PCT/US2003/019808, herein incorporated by reference. The electrodes were films of titanium 5 nanometers thick covered with films of gold 50 nm thick, patterned into wires 1 micron wide that were separated by a 50 micron gap. The network of nanotubes, disposed on the substrate between the electrodes, made electrical contact with both of them. Next, a solution of 0.1% PmPV in trichloromethane was prepared. A 0.05 microliter droplet of this solution was cast onto the nanotube transistor from a micropipet.

To measure the transistors electrically, a bias voltage of 1 V was applied between the electrodes. The current between the electrodes was measured using an ammeter as a function of gate voltage and optical illumination.

First, the gate voltage was swept continually between +10 V and —10 V. The resulting curve of current versus gate voltage is called a transfer characteristic. The transistors exhibited high current for negative gate voltages and low currents for positive gate voltages. The gate voltage at which a transistor changes from high to low current is called the threshold voltage. Then the transistors were illuminated with light of wavelength 365 nm; this wavelength is at the middle of PmPV's absorption band. When the light was on, the transfer characteristics changed, in that the threshold voltage became more positive. When the light was turned off, the transfer characteristics reverted to their original values.

Next, the gate voltage was maintained at a constant value of +4 V. A transistor had a fixed, constant current in response to the bias voltage of 1 V. When the 365 nm light was turned on, this fixed current increased to a new, higher value. When the light was turned off, the current remained at the new, higher value. The current retained this high value for 16 hours.

Then, the gate voltage was swept continually between +3 V and −1 V, and the value of the current at −1 V gate voltage was recorded. When the light was off, this current was low. When the light was on, the current was high. When the light was turned off again, the current reverted to its low value.

Finally, the transistors were heated to a temperature of 120° C. The gate voltage was maintained at a constant value of −5 V. When the light was on, the current increased rapidly to a high value, and when the light was turned off, the current reverted slowly to its original low value.

Example 1 illustrates a benefit of the invention. For certain values of the gate voltage, the device changes in response to optical radiation and does not recover when the radiation is removed. For other values, the device recovers its original properties. Thus, the device is appropriate for use as an optical sensor in a camera, where light must be applied for a fixed amount of time while a shutter is open, and then the sensors must all be interrogated after the shutter is closed. Further, the device is appropriate for use as a binary memory element. It has one state before it is exposed to optical radiation, and a second state can be ‘written’ to it by exposing it to radiation. After the radiation is removed, the state of the device can be ‘read’ many times by measuring an electrical property and evaluating whether the value of the property corresponds to a device that has or has not been exposed to radiation. At any time, the memory device can be ‘erased’ by applying a gate voltage such that it recovers its original value.

### EXAMPLE 2

Transistors were fabricated as in Example 1. Multiple transistors were placed on a single substrate. One transistor was coated with PmPV as in Example 1. A second, neighboring transistor was coated with poly(3-octylthiophene-2,5,diyl), hereinafter called P3OT, which absorbs light near 550 nm. First, a solution of 0.02% P3OT by weight in trichloromethane was prepared. Then a 0.05 microliter drop of this solution was cast onto the second transistor from a micropipet.

Both transistors were measured with a fixed gate voltage of 0 V. When light of 365 nm was applied, only the transistor coated with PmPV responded, and its response persisted after the light was turned off. When light of 550 nm was applied, only the transistor coated with P3OT responded, and its response persisted after the light was turned off. Exposure to 550 nm light did not cause the transistor coated with PmPV to revert to its original value, and exposure to 365 nm light did not cause the transistor coated with P3OT to revert to its original value. Only a change in the gate voltage caused either transistor to recover its original value.

Example 2 illustrates an additional benefit of the invention. Since the spectral response of the inventive optical sensors is determined by the spectrum of the agent, there is no need for colored filters. Sensors for different colors can be fabricated on a single substrate by means of conventional lithography. Thus, they can be placed close together, enabling dense packing of sensors. Sensors for different colors can be operated simultaneously with only one set of optics like lenses, shutters, and mirrors. Thus, the inventive devices are inherently suited to be formed into arrays such as integrated multi-color systems. Arrays may be formed using the standard techniques of semiconductor microprocessing known in the art, including, but not limited to, photolithography, masking, micro-machining, etching, chemical vapor deposition, physical vapor deposition, ink-jet printing, screen printing, and masked deposition.

### DESCRIPTION OF THE DRAWINGS

FIG. 1: Scanning electron micrograph of an example device. The wide, light-colored line is one electrode. Myriad thin lines visible throughout the image are nanotubes disposed on the substrate.

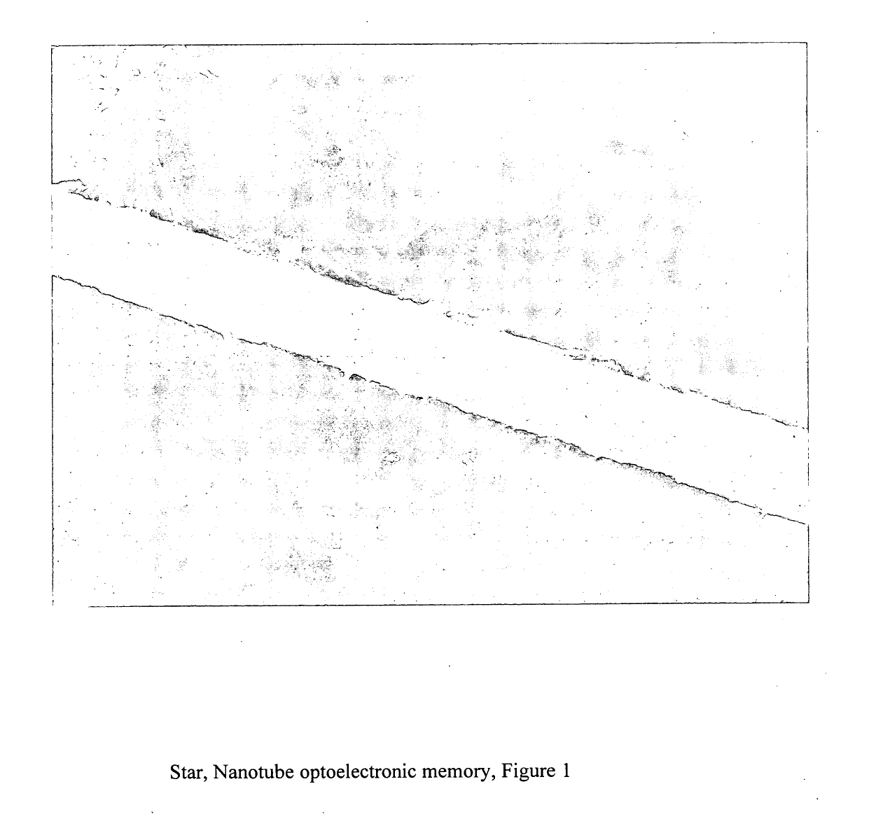

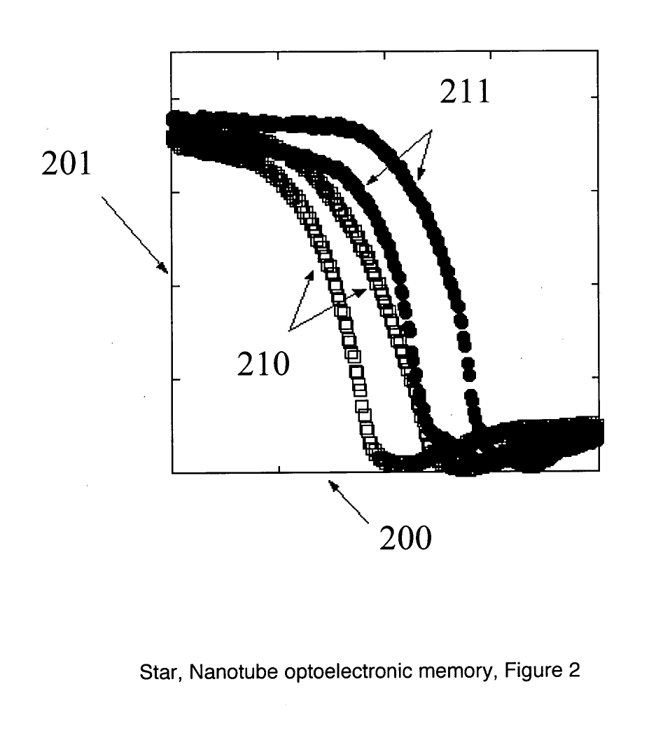

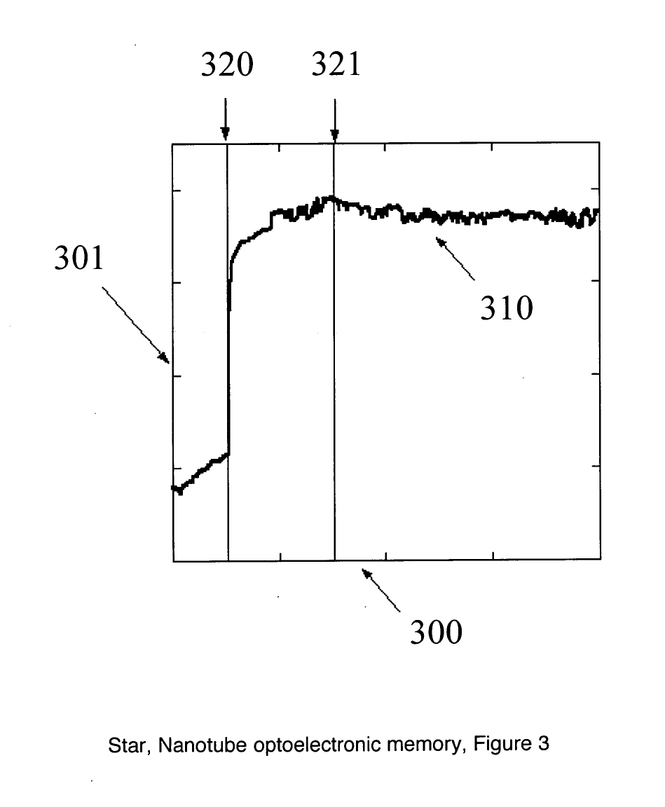

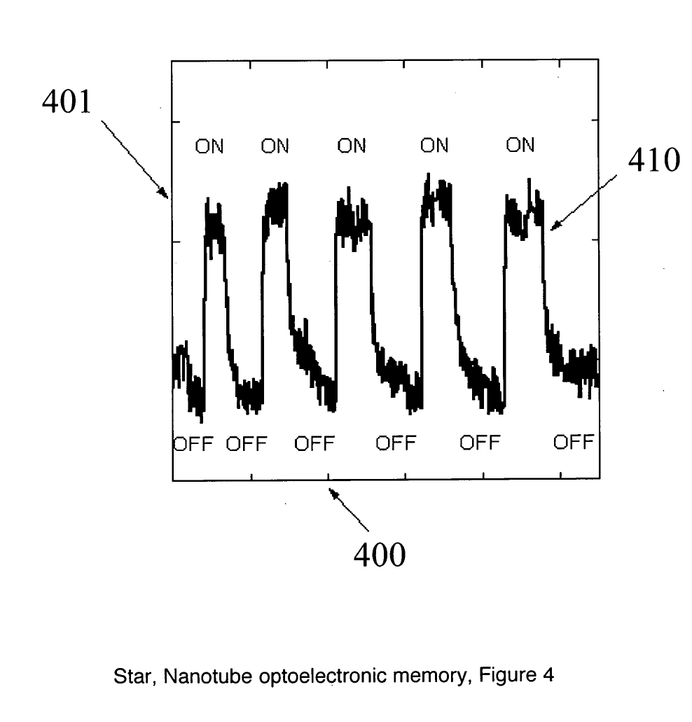

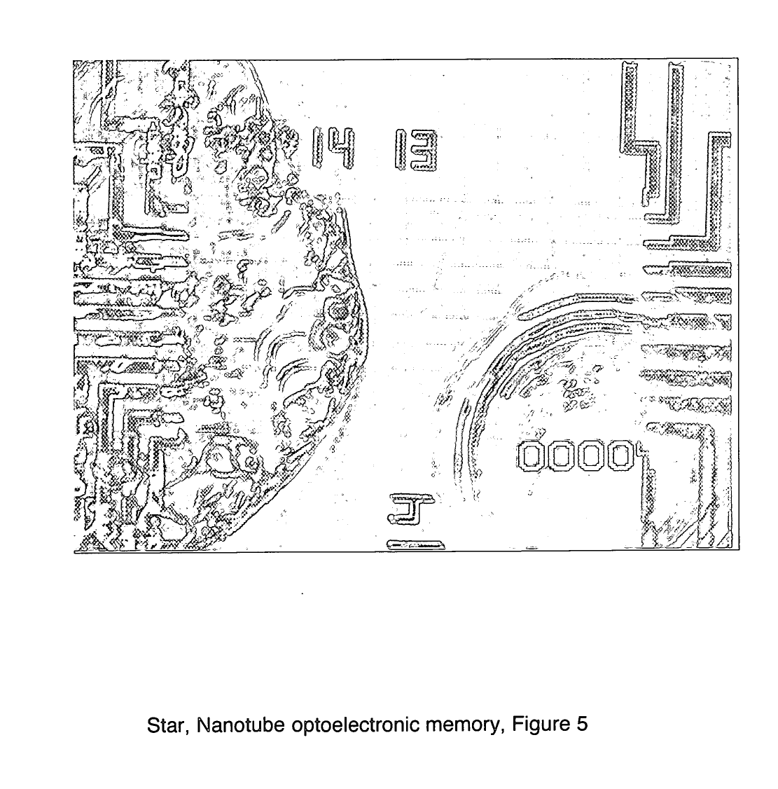

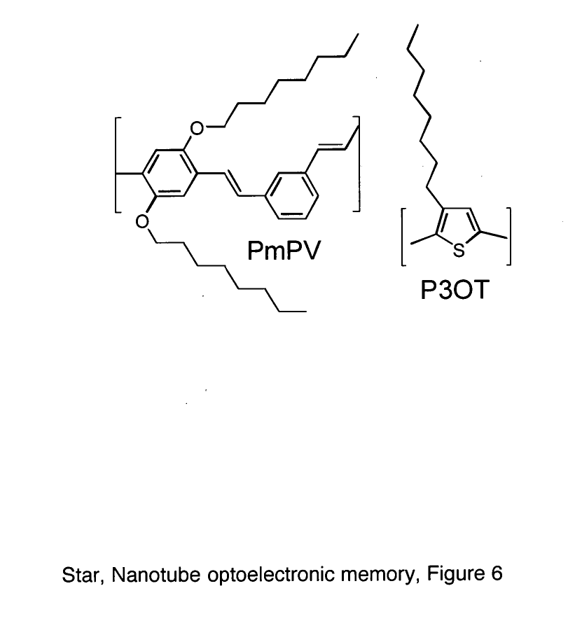

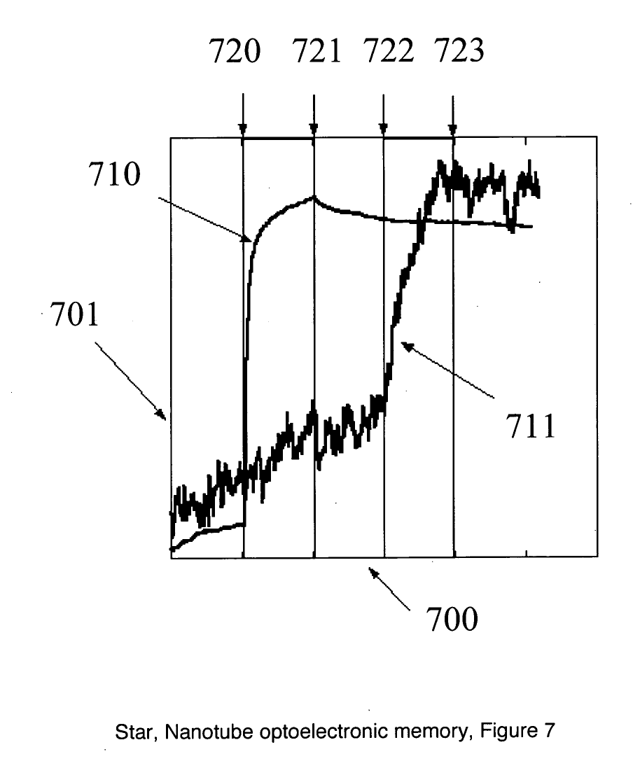

FIG. 2: Transfer characteristic with a continually changing gate voltage.
200—Axis indicating gate voltage.
201—Axis indicating current through the device.
210—Current as a function of gate voltage, sweeping the gate voltage right and then left, with no illumination.
211—Current as a function of gate voltage, sweeping the gate voltage right and then left, with steady illumination at 365 nm.

FIG. 3: Current through an example device as it is exposed to illumination, with the gate voltage fixed.
300—Axis indicating time.
301—Axis indicating current through the device.
310—Curve indicating current as a function of time.
320—Time at which the light was turned on.
321—Time at which the light was turned off.

FIG. 4: Current through an example device as it is exposed to illumination, with the gate voltage changing.
400—Axis indicating time.
401—Axis indicating current through the device.
410—Curve indicating current at the most negative gate voltage while the light is turned on and off.

FIG. 5: Optical micrograph showing two neighboring optical sensors on a single substrate. The two sensors are coated with different agents, so they respond to different colors of light.

FIG. 6: Schematic chemical structure of two example optically responsive agents.

FIG. 7: Current over time for two neighboring optical sensors as they are exposed to two different colors of light.
700—Axis indicating time.
701—Axis indicating current through the devices.
710—Curve indicating current as a function of time in a device with PmPV.
711—Curve indicating current as a function of time in a device with P3OT.
720—Time when 365 nm light was turned on.
721—Time when 365 nm light was turned off.
722—Time when 550 nm light was turned on.
723—Time when 550 nm light was turned off.

We claim:

1: An optoelectronic device comprising:
a substrate;
at least one nanotube disposed on the substrate;
at least two electrodes, said electrodes in electric communication with the at least one nanotube;
a dielectric, said dielectric in contact with at least a portion of the at least one nanotube;
a gate terminal, said gate terminal configured to have a capacitance with the at least one nanotube;
an optically responsive agent, said agent coating at least a portion of the at least one nanotube.

2: An optoelectronic device as in claim 1, wherein
the at least one nanotube is configured as a network of nanotubes.

3: An optoelectronic device as in claim 1, wherein
the at least one nanotube is a carbon nanotube, said carbon nanotube having at least one and not more than three walls.

4: An optoelectronic device as in claim 1, wherein
the dielectric is silicon oxide.

5: An optoelectronic device as in claim 1, wherein
the optically responsive agent is selected from the group consisting of poly(m-phenylenevinylene)-co-[(2,5-dioctyloxy-p-phenylene)vinylene]} and regioregular poly(3-octylthiophene-2,5-diyl).

6: An optoelectronic device as in claim 1, wherein
the optically responsive agent is a polymer comprising phenylene vinylene, phenylene ethylene, para-phenylene, thiophene, or aniline.

7: An optoelectronic device as in claim 1, wherein
the optically responsive agent is a dendrimer comprising a transition-metal complex.

8: An optoelectronic device as in claim 1, wherein
the optically responsive agent is selected from the group consisting of synthetic porphyrins and metalloporphyrins.

9: A method for detecting light comprising the steps of:
a) providing at least one nanotube in electrical communication with two electrodes, said at least one nanotube at least partially coated by an optically responsive agent, said at least one nanotube having a capacitance to a gate terminal;
b) measuring a first value of an electrical property of the nanotube as voltages are applied to the gate terminal, the voltages sweeping continuously between a first voltage and a second voltage;
c) shining optical radiation onto the nanotube;
d) measuring a second value of said electrical property while the optical radiation is shining on the nanotube;
e) comparing the second value with the first value to determine if there is a change;
f) correlating the change to pre-determined criteria to determine whether light has been detected

10: A method for detecting light comprising the steps of:
a) providing at least one nanotube in electrical communication with two electrodes, said at least one nanotube at least partially coated by an optically responsive agent, said at least one nanotube having a capacitance to a gate terminal;
b) applying a first voltage to the gate terminal;
c) measuring a first value of an electrical property of the nanotube while the first voltage continues to be applied to the gate terminal;
d) applying a second voltage to the gate terminal;
e) shining optical radiation onto the nanotube for a predetermined period of time;
d) measuring a second value of said electrical property of the nanotube while the optical radiation is shining on the nanotube;
e) comparing the second value with the first value to determine if there is a change;
f) correlating the change to pre-determined criteria to determine whether light has been detected.

11: A method for detecting light as in claim 10, further comprising the step of
applying a third gate voltage between the at least one nanotube and the gate electrode, said third gate voltage having the same value as the first gate voltage.

12: A method for detecting light as in claim 10, wherein the electrical property is electrical resistance.

13: A method for detecting light as in claim 10, wherein the electrical property is electrical current.

14: A method for detecting light as in claim 13, wherein exposing the at least one nanotube to optical radiation further comprises waiting for a predetermined duration of time.

15: A method for storing information comprising the steps of
a) providing at least one nanotube in electrical communication with two electrodes, said at least one nanotube at least partially coated by an optically responsive agent, said at least one nanotube having a capacitance to a gate terminal;
b) applying a first voltage to the gate terminal;
c) measuring a first value of an electrical property of the nanotube while the first voltage continues to be applied to the gate terminal;
d) applying a second voltage to the gate terminal;
e) shining optical radiation onto the nanotube;
d) waiting for a first predetermined period of time;
e) removing the optical radiation;
f) waiting for a second undetermined period of time;
g) measuring a second value of said electrical property while the second voltage continues to be applied to the gate terminal;
h) comparing the second value with the first value to determine if there is a change;
i) correlating the change to pre-determined criteria to determine whether the nanotube is considered to have stored a value of “1” or “0”.

16: An optoelectronic device, comprising:
a substrate;
at least one first nanotube disposed on the substrate;
at least one second nanotube disposed on the substrate;
at least two first electrodes, said electrodes in electrical communication with the at least one first nanotube;
at least two second electrodes, said electrodes in electrical communication with the at least one second nanotube;
a first optically responsive agent, said agent partially coating the at least one first nanotube; and
a second optically responsive agent, said agent partially coating the at least one second nanotube.

17: An optoelectronic device as in claim 16, wherein
the first optically responsive agent is poly{(m-phenylenevinylene)-co-[(2,5-dioctyloxy-p-phenylene)vinylene]} and the second optically responsive agent is regioregular poly(3-octylthiophene-2,5-diyl).

18: An optoelectronic device as in claim 16, further comprising
a gate terminal, said gate terminal forming a capacitance with the at least one first nanotube.

19: An optoelectronic device as in claim 18, further comprising
a second gate terminal, said second gate terminal forming a capacitance with the at least one second nanotube.

20: An optoelectronic device as in claim 16, wherein
the first optically responsive agent is chemically distinct from the second optically responsive agent.

21: An optoelectronic device as in claim 20, wherein
the second optically responsive agent has a substantially different optical spectrum from the first optically responsive agent.
